(19) United States
(12) Patent Application Publication
(10) Pub. No.: US 2025/0226034 A1
(43) Pub. Date: Jul. 10, 2025

(54) PROGRAMMING MULTIPLE ERASE BLOCKS COUPLED TO A SAME STRING

(71) Applicant: Micron Technology, Inc., Boise, ID (US)

(72) Inventors: Shyam Sunder Raghunathan, Woodlands (SG); Akira Goda, Setagaya (JP)

(21) Appl. No.: 19/012,171

(22) Filed: Jan. 7, 2025

Related U.S. Application Data
(60) Provisional application No. 63/619,404, filed on Jan. 10, 2024.

(51) Int. Cl. G11C 16/10; G11C 16/04; G11C 16/16; G11C 16/34

(52) U.S. Cl. CPC G11C 16/10; G11C 16/0483; G11C 16/16; G11C 16/3459

(57) ABSTRACT

A method can comprise applying, to program memory cells of a first erase block coupled to a first string of a memory array, a seed voltage through a sense line coupled to the first string. The method can further comprise applying, to program memory cells of the first erase block sequentially from a source side to a drain side, a respective programming voltage to access lines of the first erase block sequentially from a first access line of the first erase block to a second access line of the first erase block. The first access line can be located adjacent to one or more dummy access lines separating the first erase block from a second erase block coupled to the first string. The second access line can be located at the drain side of the first string.

### PRIORITY INFORMATION

This application claims the benefit of U.S. Provisional Application No. 63/619,404, filed on Jan. 10, 2024, the contents of which are incorporated herein by reference.

### TECHNICAL FIELD

Embodiments of the disclosure relate generally to memory systems, and more specifically, relate to apparatuses and methods for programming multiple erase blocks coupled to a same string.

### BACKGROUND

A memory system can include a memory sub-system, which can be a storage device, a memory module, or a hybrid of a storage device and a memory module. Examples of a storage device include a solid-state drive (SSD), a Universal Flash Storage (UFS) drive, a secure digital (SD) card, an embedded Multiple Media Card (eMMC), and a hard disk drive (HDD). Examples of memory modules include a dual in-line memory module (DIMM) and various types of non-volatile dual in-line memory modules (NVDIMMs). Memory systems include one or more memory components (e.g., memory devices) that store data. The memory components can be, for example, non-volatile memory components (e.g., NAND flash memory devices) and volatile memory components (e.g., DRAM devices). In general, a host system can utilize a memory system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example portion of a memory system including a memory device having an array in accordance with various embodiments of the present disclosure.

FIG. 2 is a schematic diagram illustrating an example memory array in accordance with various embodiments of the present disclosure.

FIG. 3 illustrates a portion of a memory array having multiple erase blocks per string in accordance with various embodiments of the present disclosure.

FIG. 4 schematically illustrates an example portion of a memory array having multiple erase blocks per string in accordance with various embodiments of the present disclosure.

FIG. 5 schematically illustrates another example portion of a memory array having multiple erase blocks per string in accordance with various embodiments of the present disclosure.

FIG. 6 is a flow diagram that illustrates an example method for programming multiple erase blocks coupled to a same string in accordance with various embodiments of the present disclosure.

FIG. 7 illustrates an example computing system having a memory system for programming multiple erase blocks coupled to a same string in accordance with various embodiments of the present disclosure.

### DETAILED DESCRIPTION

Aspects of the present disclosure are directed to apparatuses and for programming multiple erase blocks coupled to a same string. Various types of memory, such as NAND flash memory, include a memory array of many memory cells that can be arranged in row and column fashion and grouped in physical blocks. The cells can include a storage node such as a floating gate or charge-trap layer which allows the cells to be programmed to store one or more bits by adjusting the charge on the storage node. Generally, an erase operation (e.g., a “block erase”) is performed to erase all of the cells of a block together as a group.

Three-dimensional (3D) flash memory (e.g., a 3D NAND memory array) can include multiple strings of memory cells with each string comprising multiple series-coupled (e.g., source to drain) memory cells in a vertical direction, with the memory cells of a string sharing a common channel region. Each memory cell of a string can correspond to a different tier of the memory array, with a group of strings sharing multiple access lines, which may be referred to as word lines (WLs). Each access line can be coupled to respective memory cells of each string in the group of strings (e.g., the memory cells of a particular tier of the memory array). Groups of strings are coupled to respective sense lines, which may be referred to as data lines or bit lines (BLs), of a group of sense lines. The cells of the strings can be positioned between a drain-side select gate (referred to as a select gate drain (SGD)) and a source-side select gate (referred to as select gate source (SGS)) used to control access to the strings.

A 3D memory array can comprise multiple blocks each comprising a plurality of memory pages (e.g., physical pages of cells that can store one or more logical pages of data). In various previous approaches, a block of memory cells corresponds to a smallest group of memory cells that can be erased.

Programming memory cells (e.g., of a block) of the 3D memory array involves imposing a seed voltage on (alternatively referred to as “pre-charging”) the strings and applying a programming voltage to a selected word line, while applying programming pass voltages to unselected word lines of the block. The seed voltage is able to be passed (along the string) through word lines that are biased with low voltages (such as 0V because memory cells coupled to the word lines are in an erased stated). Subsequent to this “seeding” stage, word line voltages (e.g., voltages at which word lines are biased) are increased (e.g., from 0V) to a particular level corresponding to a program pass voltage (Vpass) for a channel boost. The increase in word line voltages is alternatively referred to as a word line voltage swing. Some prior approaches may apply a seed voltage through the “source side” (e.g., from a source line) to program sequentially from those pages located closer to the “drain side” to those pages located closer the “source side”. This programming sequence of the prior approaches avoids the situation where the seed voltage would have to pass the word lines coupled to already-programmed memory cells; thereby, requiring the word lines to have a relatively high voltage in order to enable the seed voltage to be passed, which subsequently reduces the word line voltage swing to the pass voltage; thereby, reducing the channel boost. However, these approaches can suffer various drawbacks when trying to provide an ability to erase some memory cells of a block while maintaining data in other memory cells of the block. For example, if a first group of cells (located closer/adjacent to a “drain side) within a block share a string with a second group of cells (located closer/adjacent to a “source side”) within the same block, programming the first group of cells necessarily involves passing the seed voltage (from the source line) throughout those word lines coupled to the second group of memory cells. If the second group of memory cells are already programmed, a relatively high voltage at which the word lines (coupled to the second group of memory cells) are biased is necessary to pass the seed voltage through the word lines. Further, this relatively high voltage can further reduce the word line voltage swing to the Vpass voltage (because the word line voltages are increased from a voltage level higher than 0V); thereby, reducing the channel boost.

Further, those approaches mentioned above can suffer various disturb-related drawbacks. For example, if a first group of cells within a block share a string with a second group of cells within the same block, memory operations (e.g., program operations, and/or program verify operations, etc.) performed on the first group of cells (e.g., the “aggressor group”) can lead to disturb of the second group of cells (e.g., the “victim group”). Such disturb results in threshold voltage (Vt) shifts of the victim group of memory cells, which can result in increased bit error rates (BERs) and/or loss of data. The disturb, which can be referred to as “program disturb” or “program verify disturb” herein, can accumulate (e.g., increase) over time on the victim group as the aggressor group of cells experiences repeated program/erase (PE) cycling. The accumulated disturb can be evidenced by lower or higher than targeted Vts of the victim group. Additionally, the amount of disturb on the victim group is a function of the program pass voltage applied to the corresponding victim word lines. For example, the amount of disturb on the victim group is higher for increased programming pass voltages and lower for decreased program pass voltages.

Various embodiments of the present disclosure address the above and other deficiencies by providing apparatuses and methods that can apply a seed voltage not only from a source side, but also from a drain side of a string to allow memory cells to be programmed sequentially from the source side to the drain side without a seed voltage having to pass through word lines coupled to those memory cells that are already programmed and located closer/adjacent to the source side. Further, embodiments of the present disclosure can mitigate disturb by providing a flexible adjustment of various configurations associated with programming and/or program verify operations. The configurations can include voltage levels of program pass voltages respectively applied to different decks, a sequence in which voltage levels of select gates and word lines are ramped down during the program verify operations, a threshold voltage of dummy memory cells, and/or individual program pass voltages respectively applied to dummy word lines during PE cycling, etc.

As used herein, an “erase block” refers to a group of cells that are configured to be erased together as a group and that share a same string as one or more additional groups of cells (e.g., one or more additional erase blocks). An erase block may also be referred to as a “deck.” In embodiments of the present disclosure, erase blocks can be separated by “dummy” word lines that are respectively coupled to “dummy” memory cells.

As used herein, the term “drain side” refers to a location corresponding to and/or closer to a bit line (alternatively referred to as “sense line”), while the term “source side” refers to a location corresponding to and/or closer to a source line. For example, a seed voltage from the drain side refers to a seed voltage applied through the bit line. Vice versa, a seed voltage from the source side refers to a seed voltage applied through the source line.

In contrast to previous page mapping approaches in which word lines of a physical block are programmed in sequential order either from a drain side or from a source side, embodiments of the present disclosure can include implementing different page maps for different erase blocks (e.g., decks) corresponding to a same physical block (e.g., multiple decks corresponding to a same string). For example, if a physical block has two decks, the first deck can be programmed source-to-drain (e.g., in a sequential order from a word line nearest the source side to a word line nearest the drain side), and the second deck can be programmed drain-to-source (e.g., in a sequential order from a word line nearest the drain side to a word line nearest the source side), or vice versa. As described further herein, in various embodiments, the different decks corresponding to a physical block can be programmed in a “center-to-edge” manner in order to take advantage of a seed voltage from the source side and a seed voltage from the drain side such that the seed voltage does not have to pass through programmed word lines. For example, a deck located adjacent to the drain side can be programmed in a source-to-drain manner (e.g., from a word line located closest to a center of the string toward the word line closest to the drain/edge of the string), and a deck located adjacent to the source side can be programmed in a drain-to-source manner (e.g., from a word line located closest to a center of the string toward the word line closest to the source/edge of the string).

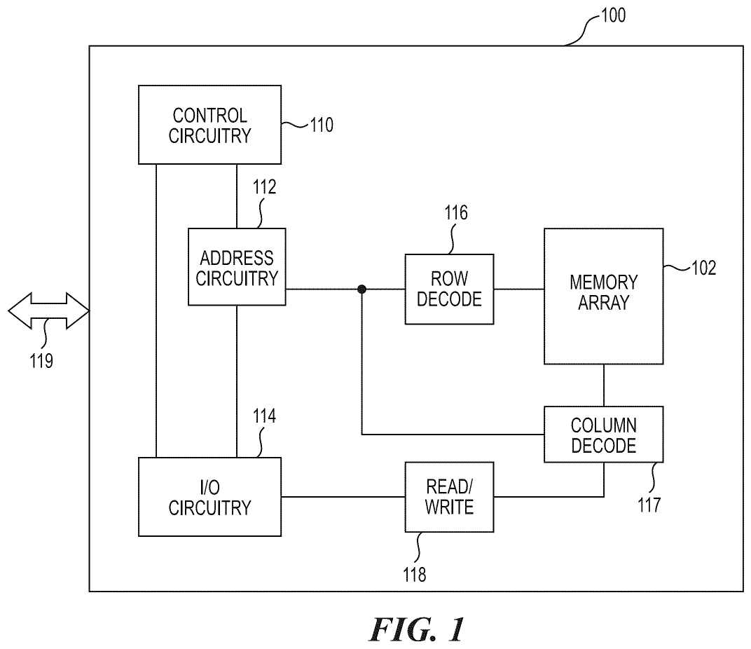

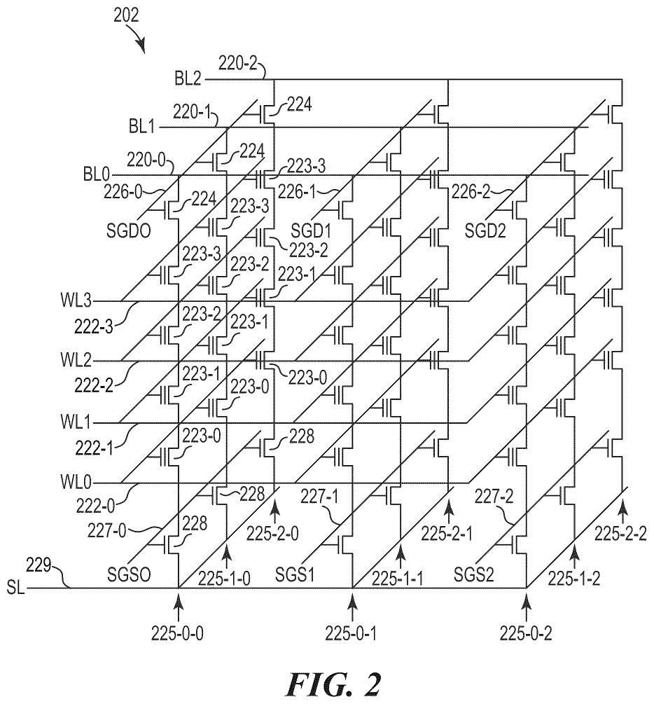

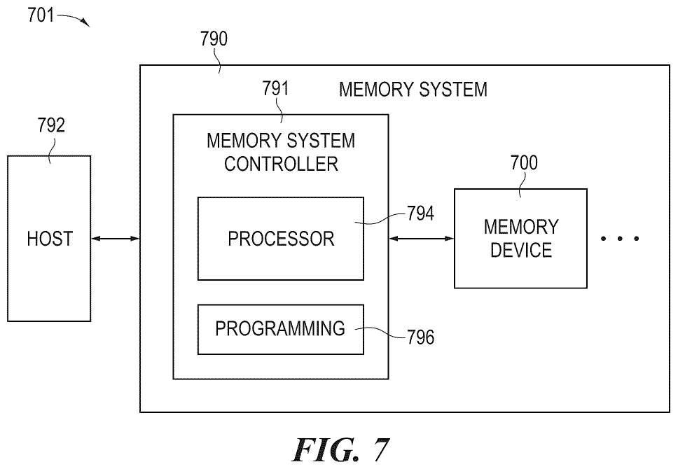

FIG. 1 illustrates an example portion of a memory system including a memory device 100 having an array 102 in accordance with various embodiments of the present disclosure. The memory array 102 can be a 3D NAND array such as described further in association with FIG. 2, for example. The array can comprise single level cells (SLCs) storing 1 bit per cell, multilevel cells (MLCs) storing 2 bits per cell, triple level cells (TLCs) storing three bits per cell, or quad level cells (QLCs) storing 4 bits per cell, for example. Embodiments are not limited to a particular type of memory cell. The memory device 100 can be part of a memory system such as memory system 790 described in FIG. 7.

The memory device 100 includes control circuitry 110, address circuitry 112, input/output (I/O) circuitry 114 used to communicate with an external device via an interface 119, which may be a bus used to transmit data, address, and control signals, among other signals between the memory device 100 and an external host device, which can include a controller, host processor, etc., that is capable of accessing the memory array 102. The interface 119 can include a combined address, control, and data bus or separate busses depending on the particular physical interface and corresponding protocol. The interface 119 can be an Open NAND Flash Interface (ONFI) interface or a Non-Volatile Memory Express (NVMe) interface; however, embodiments are not limited to a particular type of interface or protocol.

The control circuitry 110 can decode signals (e.g., commands) received via interface 119 and executed to control operations performed on the memory array 102. The operations can include data programming operations, which may be referred to as write operations, data read operations, which may be referred to as sensing operations, data erase operations, etc. The control circuitry 110 can cause various groups of memory cells (e.g., pages, blocks, erase blocks, etc.) to be selected or deselected in association with performing memory operations on the array 102. The control circuitry 110 can comprise a state machine, a sequencer, and/or some other type of control circuitry, which may be implemented in the form of hardware, firmware, or software, or any combination thereof.

The I/O circuitry 114 is used for bi-directional communication of data between the memory array 102 and the external host via interface 119. The address circuitry 112, which can include a register, can latch address signals received thereto, and the address signals can be decoded by a row decoder 116 and a column decoder 117 to access the memory array 102. The memory device 100 includes read/write circuitry 118 used to read data from and write data to the memory array 102. As an example, the read/write circuitry can include various latch circuitry, drivers, sense amplifiers, buffers, etc. Data can be read from the memory array 102 by sensing voltage and/or current changes on bit lines of the memory array 102.

FIG. 2 is a schematic diagram illustrating an example memory array 202 in accordance with various embodiments of the present disclosure. The memory array 202 can be located in a memory device such as memory device 100 described in FIG. 1, for example. The memory array 202 is a 3D NAND array.

The memory array 202 comprises a number of access lines (word lines) 222-0 (WL0), 222-1 (WL1), 222-2 (WL2), and 222-3 (WL3) and a number of sense lines (bit lines) 220-0 (BL0), 220-1 (BL1), and 220-2 (BL2) coupled to multiple strings 225-0-0, 225-0-1, 225-0-2, 225-1-0, 225-1-1, 225-1-2, 225-2-0, 225-2-1, and 225-2-2. The word lines, bit lines, and strings are collectively referred to as word lines 222, bit lines 220, and strings 225, respectively. Although four word lines 222, three bit lines 220, and nine strings 225 are shown, embodiments are not so limited.

Each of the strings 225 comprises a number of memory cells (referred to collectively as memory cells 223) located between a select transistor 224 and a select transistor 228. For example, as shown in FIG. 2, strings 225-0-0, 225-1-0, and 225-1-2 each respectively comprise memory cells 223-0, 223-2, 223-2, and 223-3 located between select transistors 224 and 228 (e.g., respective drain-side select gate (SGD) 224 and source-side select gate (SGS) 228). The memory cells 223 can be floating gate or charge-trap transistors with the cells 223 of a given string 225 sharing a common channel region (e.g., pillar). As shown, the memory cells 223 of a given string are series-coupled source to drain between the SGD transistor 224 and the SGS transistor 228.

The memory cells 223 of the strings 225 are stacked vertically such that they are located on distinct tiers/levels of the memory array 202. Each word line 222 can be commonly coupled to all the memory cells at a particular tier/level. For example, word line 222-0 can be coupled to (e.g., as the control gate) the nine memory cells 223-0 corresponding to the nine respective strings 225.

The select transistors 224 and 228 can be controlled (e.g., turned on/off) via the corresponding select gate signals SGD0, SGD1, SGD2, SGS0, SGS1, and SGS2 in order to couple the strings 225 to their respective bit lines 220 and a common source line (SL) 229 during memory operations (e.g., reads, writes, erases). As shown in FIG. 2, the select gate signals SGD0, SGD1, and SGD2 are provided (e.g., to the gates of transistors 224) via respective conductive lines 226-0, 226-1, and 226-2, and the select gate signals SGS0, SGS1, and SGS2 are provided (e.g., to the gates of transistors 228) via respective conductive lines 227-0, 227-1, and 227-2. Although the signals SGS0, SGS1, and SGS2 are shown on separate conductive lines 227, in some embodiments the conductive lines 227-0, 227-1, and 227-2 may be coupled via a common SGS line.

To perform memory operations on the array 202, particular voltages can be applied to the word lines 222, bit lines 220, sense line 220, and/or source line 229. The particular voltages applied depend on the memory operation being performed, and different voltages may be applied to the word lines 222 during a particular memory operation in order to program data to (e.g., store data in) a cell (or page of cells) or read data from a cell.

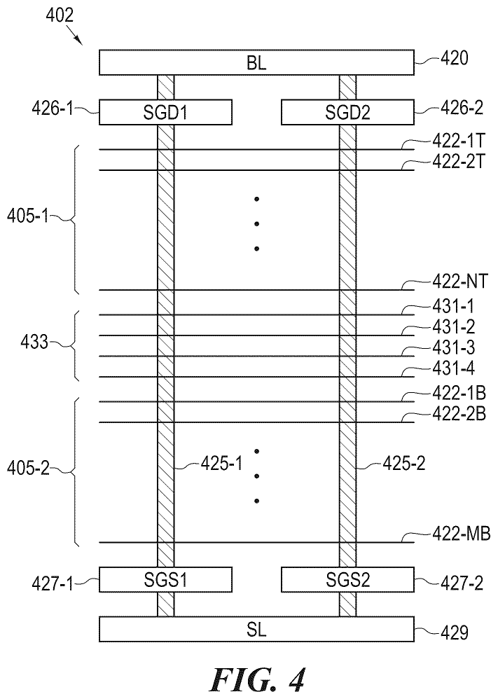

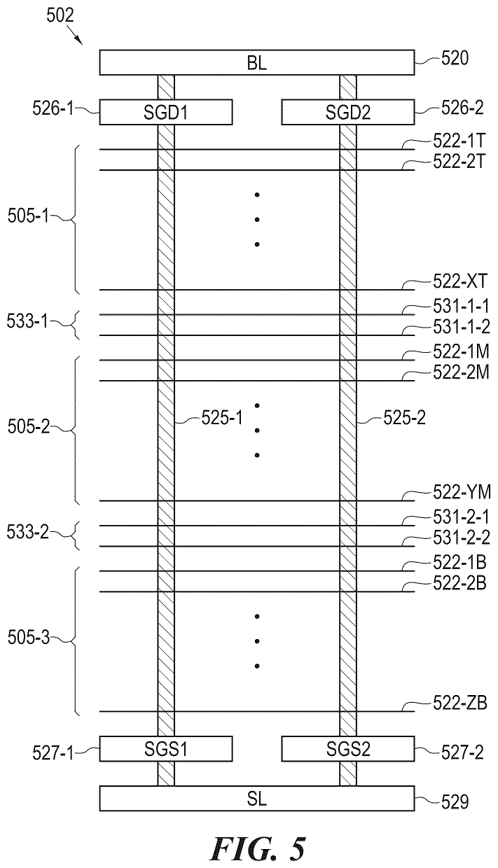

For example, a programming operation to store data in a selected memory cell of string selected to store information into memory cell 223 involves a “seeding” phase, in which a seed voltage can be supplied from either drain or source side of the array 202 (e.g., by applying a seed voltage through a bit line 220 or source line 229 coupled to one or more strings that are further coupled to one or more selected cells being programmed) and a voltage (e.g., alternatively referred to as “seed pass voltage” that may have a voltage level lower than that of the seed voltage) is applied to word lines 421 and 431 to pass the seed voltage through the selected word lines 222 (but not through the word lines 222 corresponding to those cells that are in a programmed state). Subsequent to the seeding phase, a voltage (e.g., a programming voltage, Vpgm) can be applied to the selected word line corresponding to the selected cells, while other voltages (e.g., program pass voltages, Vpass) can be applied to the unselected word lines coupled to non-selected cells (e.g., the memory cells not being programmed). A seed voltage can be from either side (e.g., drain or source side) of the memory array 202 depending on whether a deck (e.g., decks 405-1, 405-2, 505-1, 505-2, 505-3 illustrated in FIGS. 4-5) to be and/or being programmed is located closer (or adjacent) to the drain or source side. Further details of applying a seed voltage through bit lines 220 or sense line 229 are described in connection with FIGS. 4-6.

A programming operation further involves performing program verify operations to determine when the Vt of the cells being programmed have reached a desired level. As such, a program verify operation essentially involves performing a read operation on the selected cells (e.g., the cells coupled to the selected word line). For example, a read operation and/or a program verify operation can involve applying a read voltage (Vread) to the selected word line (SELECTED WLn), while applying a read pass voltage (alternatively referred to as “program verify pass voltage) (Vpassr, Vpassr1, or Vpass_v) to the unselected word lines of the string. The read and/or program verify pass voltage is designed to place the unselected cells of a string in a conductive state in order to allow current to flow through the string depending on the applied read voltage (Vread) and Vt of the selected cell. In this manner, the read or program verify operation can be used to determine if the Vt of the selected cell is above or below a particular level (e.g., above or below Vread).

During program verify operations, a situation can arise where an electric field is generated between a specific word line (coupled to the memory cells being verified via the program verify operation) and the neighboring word lines (coupled to memory cells that are either not being verified or are in an erased state, or both) that can be large enough to cause the disturb (e.g., hot electron disturb) on the neighboring word lines. This electric field can occur while the voltage on the word line associated with the memory cells being verified (alternatively referred to as word line being verified) is being ramped down to complete the program verify operation.

In embodiments of the present disclosure, this disturb can be mitigated by providing various means to reduce the electric field during the voltage ramp down at the end of program verify operation. In one embodiment, dummy memory cells coupled to dummy word lines (e.g., dummy word lines located either between a sense line 420, 520 and the deck 405-1, 505-1 or a source line 429, 529 and the deck 405-2, 505-3, although not illustrated in FIGS. 4-5) can be programmed to have a higher threshold voltage, such as 2V (e.g., a threshold voltage higher than a threshold voltage corresponding to an erased state). This helps drop some channel potential near the select gates 426, 526, 427, 527, which in turn helps lower the electric field across the strings 425, 525 (as compared to the prior approaches to program verify operations); thereby, mitigating the disturb during program verify operations.

In another embodiment, program verify operations can be performed in the same manner as read operations are performed in association with a sequence in which voltages are ramped down. Previous approaches typically involved first ramping down the voltage on the word line being verified, followed by the ramping down of voltages on the select gate source/drain (SGD) lines and/or select gate source (SGS) lines. In contrast, in a number of embodiments, a different approach can be employed. For example, the voltages on the SGD lines (e.g., SGD lines 226) and SGS lines (e.g., SGS lines 227) can be ramped down before the voltage ramp down on the word line being verified during program verify operations. This alternative sequence helps drop some channel potential near the select gates 426, 526, 427, 527, which in turn helps lower the electric field across the strings 425, 525 (as compared to the prior approaches to program verify operations); thereby, mitigating the disturb during program verify operations.

An erase operation to remove data from a selected group of memory cells (e.g., a selected erase block as described further below) can include applying a relatively high voltage (e.g., 20V) to the source line 229, the relatively high voltage (e.g., 20V) to unselected word lines (e.g., word lines coupled to cells of an erase block not being erased), and a relatively low voltage (e.g., 0V) to the selected word lines (e.g., the word lines coupled to the erase block being erased), which reduces their Vt levels to near 0V; thereby, resulting in erasing of the cells of the selected erase block.

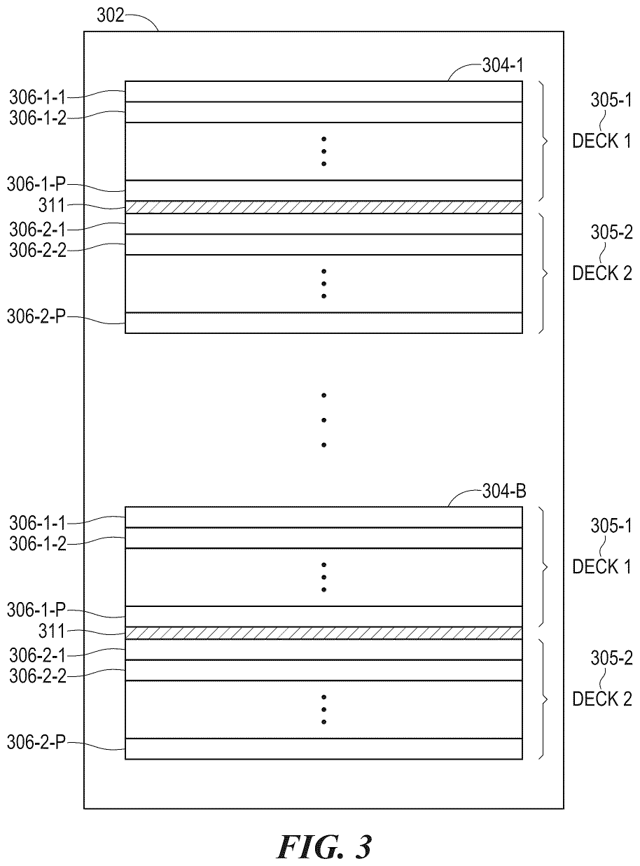

The memory cells 223 of the array 202 can represent a physical block of memory cells that can comprise multiple (e.g., two or more) physical erase blocks (alternatively referred to as “decks” as described herein), such as decks 305-1, 305-2 illustrated in FIG. 3. As an example, the word lines 222-0 and 222-1 can be coupled to cells of a first erase block, and the word lines 222-2 and 222-3 can be coupled to cells of a second/different erase block, although embodiments are not limited to a particular quantity of erase blocks coupled to a same string. Therefore, the cells 223-0 and 223-1 of the nine respective strings 225 (e.g., the cells of the first erase block) share respective common strings with the cells 223-2 and 223-3 (e.g., the cells of the second erase block). In operation, erase blocks can be separately (e.g., individually) selected or deselected. For example, an erase operation can be performed on a selected first erase block corresponding to a group of strings while other erase block(s) corresponding to the same group of strings is deselected (e.g., such that is not erased).

As further described herein, an array (e.g., 202) can comprise a number of word lines physically between (e.g., separating) the word lines (e.g., 222) corresponding to different erase blocks. The word lines separating word lines corresponding to different erase blocks can be referred to as “dummy” word lines and can be coupled to dummy memory cells (e.g., within the strings 225) that are not used to store data. The dummy word lines and/or dummy cells can facilitate the ability to perform erase operations separately on erase blocks that share a common string or strings. The quantity of dummy word lines between erase blocks can vary, and various bias voltages can be applied to the dummy word lines during the various memory operations performed on the erase blocks.

FIG. 3 illustrates a portion of a memory array 302 having multiple erase blocks per string in accordance with various embodiments of the present disclosure. The memory array 302 includes multiple physical blocks 304-1, . . . , 304-B and can be operated in accordance with one or more embodiments of the present disclosure. The indicator “B” is used to indicate that the array 302 can include a number of physical blocks 304. As an example, the number of physical blocks in array 302 can be 128 blocks, 512 blocks, or 1,024 blocks, but embodiments are not limited to a particular multiple of 128 or to any particular number of physical blocks in an array 302. The memory array 302 can be, for example, a NAND flash memory array (e.g., a 3D NAND flash array such as array 102 and/or 202).

Each of the physical blocks 304-1, . . . , 304-B includes a first erase block 305-1 (DECK_1) and a second erase block 305-2 (DECK_2) separated by a region 311. The region 311 can comprise “dummy” word lines, for example. Although the region 311 is illustrated as not being part of the decks 305-1 and 305-2, embodiments are not so limited. For example, the region 311 can be considered as part of the deck 305-1 or 305-2. As described above, the decks 305-1 and 305-2 are commonly coupled to the strings of the blocks 304-1, . . . , 304-B with the decks 305-1 and 305-2 being separately erasable via a block erase operation (e.g., deck 305-1 can be erased without erasing deck 305-2 and vice versa). Although each physical block 304 is illustrated as having two erase blocks (e.g., erase blocks 305-1 and 305-2), embodiments are not so limited. For example, each physical block 304 can include more than two erase blocks (e.g., three erase blocks) that are commonly coupled to the strings of the respective block with each one of the three erase blocks being separately erasable, which is further described in detail in association with FIG. 5.

Each deck 305-1 and 305-2 can comprise a number of physical pages, which can correspond to a “row” of the array corresponding to a particular word line. As shown, deck 305-1 comprises pages 306-1-1, 306-1-2, . . . , 306-1-P, and deck 305-2 comprises pages 306-2-1, 306-2-2, . . . , 306-2-P. The designator “P” is used to indicate that the decks 305-1 and 305-2 can comprise a plurality of pages/rows. Each physical page (collectively referred to as pages 306) can store multiple logical pages of data. A page can refer to a unit of programming and/or reading (e.g., a group of cells that are programmed and/or read together as a functional group).

FIG. 4 schematically illustrates an example portion of a memory array 402 having multiple (e.g., 2) erase blocks per string in accordance with various embodiments of the present disclosure. The example shown can be a portion of the array 202 described in FIG. 2. The array portion 402 can be a portion of a physical block of memory cells that includes multiple erase blocks (e.g., decks).

In this example, the array 402 includes a plurality/group of word lines 422-1T, 422-2T, . . . , 422-NT corresponding to a first erase block 405-1 (e.g., a top deck) and a plurality/group of word lines 422-1B, 422-2B, . . . , 422-MB corresponding to a second erase block 405-2 (e.g., bottom deck). Although each the array 402 is illustrated as having two erase blocks (e.g., erase blocks 405-1 and 405-2), embodiments are not so limited. For example, the array 402 can include more than two erase blocks (e.g., three erase blocks) that are commonly coupled to the strings of the respective block with each one of the three erase blocks being separately erasable, which is further described in detail in association with FIG. 5. The first erase block 405-1 can be said to be located closer and/or adjacent to the drain side (e.g., including a sense line 420), while the second erase block 405-2 can be said to be located closer and/or adjacent to the source side (e.g., including a source line 429).

The designators “N” and “M” can represent various numbers (e.g., 3 or more) and “N” and “M” can be the same number. Accordingly, embodiments are not limited to a particular quantity of word lines 422 for the top deck 405-1 or bottom deck 405-2 (the designator “T” corresponding to “top” and the designator “B” corresponding to “bottom”). The array 402 also includes a number of dummy word lines 431-1, 431-2, 431-3, and 431-4, which can be collectively referred to as word lines 431. The dummy word lines 431 correspond to a separation region 433 between the top deck 405-1 and bottom deck 405-2. Although four word lines 431 are illustrated, embodiments can include more or fewer than four dummy word lines 431 separating erase blocks corresponding to same strings. Further, although the separation region 433 is illustrated as not being part of the decks 405-1 and 405-2, embodiments are not so limited. For example, the region 433 can be considered as part of the deck 405-1 or 405-2.

The array portion 404 illustrates two strings 425-1 and 425-2 for ease of illustration; however, embodiments can include many more strings 425. Memory cells are located at the intersections of the word lines 422/431 and strings 425, with the memory cells of a particular string 425 sharing a common channel region (e.g., pillar) as described in connection with FIG. 2. The dummy word lines 431 can be coupled to dummy memory cells (e.g., cells that are not addressable to store user data).

As illustrated in FIG. 4, a first end of the strings 425-1 and 425-2 can be coupled to a common source line 429 via respective select gate source lines 427-1 (SGS1) and 427-2 (SGS2). The second/opposite end of the strings 425-1 and 425-2 can be coupled to a bit line 420 via respective select gate drain lines 426-1 (SGD1) and 426-2 (SGD2). As such, the strings 425 (e.g., the cells thereof) can be individually accessed using the bit line 420 and select gates SGS1, SGS2, SGD1, SGD2 to which the lines 426-1 and 426-2 are coupled. Although only a single bit line 420 is shown, embodiments can include multiple bit lines such as shown in FIG. 2, for example.

As noted herein, in various embodiments, the top deck 405-1 and the bottom deck 405-2 can be erased via separate erase operations even though the cells of the decks 405-1/405-2 share the same strings 425-1/425-2. For example, an erase operation can be performed on the cells coupled to word lines 422-1T to 422-NT without erasing the cells coupled to the word lines 422-1B to 422-MB, and vice versa. Similarly, each one of the decks 405-1 and 405-2 can be individually programmed and/or read without programming or reading the other of the decks 405-1 and 405-2.

As described herein, programming decks 405-1, 405-2 can involve applying a seed voltage to one or more strings (e.g., strings 425-1 and 425-2) through a bit line 420 or a source line 429 and applying a seed pass voltage (e.g., having a voltage level lower than that of the seed voltage) to the word lines 422 and 431 to pass the seed voltage through the selected word line(s) 422 (but not through the word lines 422 corresponding to those cells that are in a programmed state). Subsequent to the strings 425-1, 425-2 biased at the seed voltage, a programming voltage (e.g., Vpgm) and program pass voltages (e.g., Vpass) can be respectively applied to the selected word line 422 (corresponding to the selected cells) and the unselected word lines 422 coupled to non-selected cells (e.g., the dummy memory cells and the memory cells not being programmed).

Programming both top and bottom decks 405-1, 405-2 using a seed voltage from one side (e.g., the source side) of the array 402 may be challenging when top and bottom decks 405-1, 405-2 are desired to be individually programmed without a particular sequence in which top and bottom decks 405-1, 405-2 are programmed. For example, programming the top deck 405-1 located closer to the bit line 420 can involve applying the seed voltage through the source line 429, which can be relatively easily done if the bottom deck 405-2 is in an erased state. However, if at least a portion (e.g., one or more pages) of the bottom deck 405-2 is already programmed, the seed voltage from the source line 429 would have to pass those pages of memory cells of the bottom deck 405-2 that are already programmed.

To avoid this challenge that would have occurred from the seed voltage from one side of the array 402, top and bottom decks 405-1 and 405-2 can be programmed using seed voltages from different sides (e.g., drain or source side) of the memory array 402 in order to achieve “center-to-edge” programming of those decks coupled to a same string. In “center-to-edge” programming, those memory cells located closer/adjacent to (e.g., dummy memory cells coupled to) dummy word lines 431-1, . . . , 431-4 can be programmed prior to those memory cells located either side (e.g., drain or source side) of the memory array 402. For example, a top deck 405-1 can be programmed sequentially from those memory cells coupled to a word line 422-NT to those memory cells coupled to a word line 422-1T using a seed voltage applied from the bit line 420 (e.g., from drain side). For example, a bottom deck 405-2 can be programmed sequentially from those memory cells coupled to a word line 422-1B to those memory cells coupled to a word line 422-MB using a seed voltage applied from the source line 420 (e.g., from source side). By utilizing seed voltages from both sides with the sequence employed by “center-to-edge” programming, situations, in which a seed voltage would have to pass the already programmed memory cells can be avoided.

While one deck (e.g., the top deck 405-1) is subject to a number of P/E cycles, a different deck (e.g., the bottom deck 405-2) can be also subject to the program pass voltages repeatedly applied. This different deck can be a victim deck of the disturb that is a function of the program pass voltage repeatedly applied (e.g., the amount of disturb on the victim group is higher for increased programming pass voltages). To mitigate this disturb, in some embodiments, program pass voltages applied to word lines of this different deck (that is not subject to the current P/E cycle) can have a lower voltage level than those program pass voltages applied (e.g., from the different voltage source) to the deck subjected to the current P/E cycle, which can eventually mitigate the disturb from the repeated application of the program pass voltages.

Often, as a result of applying program pass voltage having different levels as described above, decks 405 can be subject to different “boosts” (e.g., higher and lower boosts), which can create the electric field (which can be large enough to result in the disturb) on the interface (e.g., dummy word lines 431) between the decks 405. For example, the deck 405 on which program pass voltages having a relatively higher voltage level are applied can be subject to a “higher boost”, while the deck 405 on which program pass voltages having a relatively lower voltage level are applied can be subject to a “lower boost” and the disturb can occur on the interface dummy word lines 433 and due to the potential gradient between the decks 405. Even if program pass voltages having the same voltage level are applied to the decks 405, the decks 405 can be subject to different “boosts” depending on their respective states. For example, the deck 405 in a programmed state (e.g., the memory cells of the deck 405 are in a programmed state) can be subject to a “lower boost”, while the deck 405 in an erased state (e.g., the memory cells of the deck 405 are in an erased state) is subject to a “higher boost” as a result of the program pass voltages applied.

Various means can be provided to reducing a potential gradient on the strings 425; thereby, mitigating this disturb. In one embodiment, dummy memory cells coupled to the dummy word lines 431 can be programmed to have a higher threshold voltage (e.g., higher than that of memory cells in an erased state, such as from 0 to 4V), which can reduce the potential gradient on the strings 425. In another embodiment, different program pass voltages can be individually applied to the dummy word lines 431 so as to reduce the potential gradient on the strings 425. For example, consider a memory array having three dummy word lines between two decks (e.g., the top and bottom decks 405-1, 405-2). In this example, when program pass voltages with each being 8V are applied to one deck (e.g., the top deck 405-1) and program pass voltages with each being 6V are applied to the word lines of the other deck (e.g., the bottom deck 405-2), program pass voltages respectively of 8V, 7.5V, and 6.5V (alternatively 7.5V, 7V, and 6.5V) can be respectively applied to the three word lines to reduce the potential gradient on the strings 425.

FIG. 5 schematically illustrates another example portion of a memory array 502 having multiple (e.g., 3) erase blocks (e.g., decks) per string in accordance with various embodiments of the present disclosure. The example shown can be a portion of the array 202 described in FIG. 2. The array portion 502 can be a portion of a physical block of memory cells that includes multiple decks.

While the array 502 illustrated in FIG. 5 is generally analogous to the array 402 illustrated in FIG. 4, the array 502 includes 3 erase blocks 505-1, 505-2, and 505-3. For example, the array 502 includes a plurality/group of word lines 522-1T, 522-2T, . . . , 522-XT corresponding to a first erase block 505-1 (e.g., a top deck), a plurality/group of word lines 522-1M, 522-2M, . . . , 522-YM corresponding to a second erase block 505-2 (e.g., a middle deck), and a plurality/group of word lines 522-1B, 522-2B, . . . , 522-ZB corresponding to a third erase block 505-3 (e.g., bottom deck). The first erase block 505-1 can be said to be located closer and/or adjacent to the drain side (e.g., including a sense line 520), while the third erase block 505-3 can be said to be located closer and/or adjacent to the source side (e.g., including a source line 529).

The designators “X”, “Y” and “Z” can represent various numbers (e.g., 3 or more) and “X”, “Y”, and “Z” can be the same number. Accordingly, embodiments are not limited to a particular quantity of word lines 522 for the top deck 505-1, middle deck 505-2, or bottom deck 505-3 (the designator “T” corresponding to “top”, the designator “M” corresponding to “middle”, and the designator “B” corresponding to “bottom”). The array 502 also includes a first number of dummy word lines 531-1-1, 531-1-2 (collectively referred to as first dummy word lines 531) and a second number of dummy word lines 531-2-1, 531-2-2 (collectively referred to as second dummy word lines 531). The first dummy word lines 531-1-1, 531-1-2 correspond to a separation region 533-1 between the top deck 505-1 and middle deck 505-2 and the second dummy word lines 531-2-1, 531-2-2 correspond to a separation region 533-2 between the middle deck 505-2 and the bottom deck 505-3. Although two word lines 531 are illustrated for each separation region 533, embodiments can include more or fewer than two dummy word lines 531 separating erase blocks corresponding to same strings. Further, although the separation region 533 is illustrated as not being part of the decks 505-1, 505-2, and 505-3, embodiments are not so limited. For example, the region 533-1 can be considered as part of the deck 505-1 or 505-2 and the region 533-2 can be considered as part of the deck 505-2 or 505-3.

The array portion 504 illustrates two strings 525-1 and 525-2 for ease of illustration; however, embodiments can include many more strings 525. Memory cells are located at the intersections of the word lines 522/531 and strings 525, with the memory cells of a particular string 525 sharing a common channel region (e.g., pillar) as described in FIG. 2. The dummy word lines 531 can be coupled to dummy memory cells (e.g., cells that are not addressable to store user data).

As illustrated in FIG. 5, a first end of the strings 525-1 and 525-2 can be coupled to a common source line 429 via respective select gate source lines 527-1 (SGS1) and 527-2 (SGS2). The second/opposite end of the strings 525-1 and 525-2 can be coupled to a bit line 520 via respective select gate drain lines 526-1 (SGD1) and 526-2 (SGD2). As such, the strings 525 (e.g., the cells thereof) can be individually accessed using the bit line 520 and select gates SGS1, SGS2, SGD1, SGD2 to which the lines 526-1 and 526-2 are coupled. Although only a single bit line 520 is shown, embodiments can include multiple bit lines such as shown in FIG. 2, for example.

As noted herein, in various embodiments, the top deck 505-1, the middle deck 505-2, and the bottom deck 505-3 can be erased via separate erase operations even though the cells of the decks 505-1/505-2/505-3 share the same strings 525-1/525-2. For example, an erase operation can be performed on the cells coupled to word lines 522-1T to 522-XT without erasing the cells coupled to the word lines 522-1M to 522-YM and/or the word lines 522-1B to 522-ZB, and vice versa. Similarly, each one of the decks 505-1, 505-2, 505-3 can be individually programmed and/or read without programming or reading the other of the decks 505-1, 505-2, 505-3.

As described herein, programming decks 505-1, 505-2, and/or 505-3 can involve a seeding phase, in which a seed voltage is supplied (e.g., applied) through a bit line 520 or a source line 529 coupled to one or more strings (e.g., strings 525-1 and 525-2 and that are further coupled to one or more selected cells being programmed) and applying a relatively low voltage (e.g., having a voltage level lower than the seed voltage) to the word lines 522 and 531 to pass the seed voltage through the selected word lines 522 (but not through the word lines 522 corresponding to those cells that are in a programmed state). Subsequent to the strings biased at the seed voltage, a programming voltage (e.g., Vpgm) and program pass voltages (e.g., Vpass) can be respectively applied to the selected word line 522 (corresponding to the selected cells) and the unselected word lines 522 coupled to non-selected cells (e.g., the dummy memory cells and the memory cells not being programmed).

Top, middle, and bottom decks can be programmed using a seed voltage from either (e.g., drain or source side) side of the memory array 502. For example, a top deck 505-1 can be programmed sequentially from those memory cells coupled to a word line 522-XT to those memory cells coupled to a word line 522-1T using a seed voltage applied through the bit line 520. For example, a bottom deck 505-3 can be programmed sequentially from those memory cells coupled to a word line 522-1B to those memory cells coupled to a word line 522-ZB using a seed voltage applied through the source line 529.

A middle deck 505-2 can be programmed using a seed voltage from either side of the array 502. For example, a middle deck 505-2 can be programmed sequentially from those memory cells coupled to a word line 522-YM to those memory cells coupled to a word line 522-1M using a seed voltage applied through the bit line 520. In this example, the middle deck 505-2 can be programmed in a such sequence prior to the top deck 505-1 to achieve “center-to-edge” programming. Alternatively speaking, the top deck 505-1 can remain as an erased state until the middle deck 505-2 is programmed. Another example, a middle deck 505-2 can be programmed sequentially from those memory cells coupled to a word line 522-1M to those memory cells coupled to a word line 522-YM using a seed voltage applied through the source line 529. In this example, the middle deck 505-2 can be programmed in a such sequence prior to the bottom deck 505-1 to achieve “center-to-edge” programming. Alternatively speaking, the bottom deck 505-3 can remain as an erased state until the middle deck 505-2 is programmed.

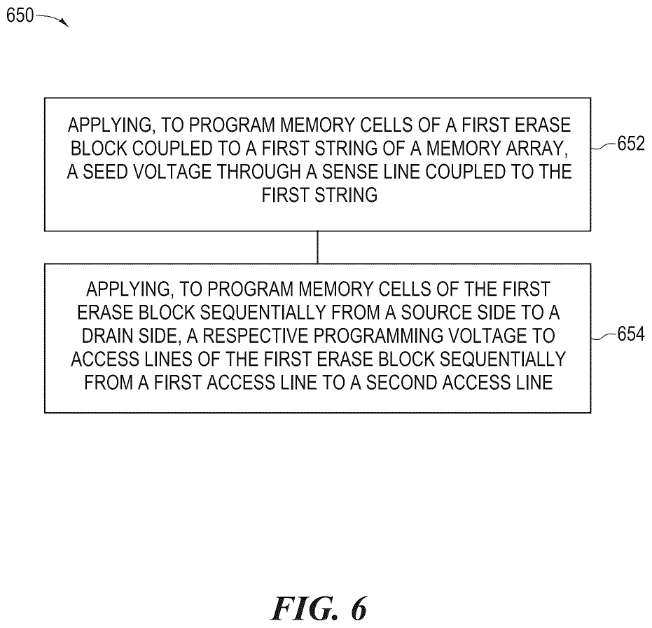

FIG. 6 is a flow diagram that illustrates an example method 650 for programming multiple erase blocks coupled to a same string in accordance with various embodiments of the present disclosure. The method 650 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 650 is performed by the control circuitry 110 of FIG. 1 and/or the controller 791 of FIG. 7. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 652, a seed voltage can be applied through a sense line (e.g., sense line 220, 420, 520 illustrated in FIGS. 1-5) coupled to a first string (e.g., string 225, 425, 525 illustrated in FIGS. 2 and 4-5) to program memory cells of a first erase block (e.g., erase block 305-1, 405-1, 505-1, and/or 505-2 illustrated in FIGS. 3-5) coupled to the first string 225, 425, 525. Further, a seed pass voltage can be further applied to those word lines (e.g., word lines 222, 422, 431, 522, 531 illustrated in FIGS. 2 and 4-5) coupled to the first string 225, 425, 525. In some embodiments, the seed pass voltage can have a lower voltage level (e.g., 0-1V) than that of the seed voltage (e.g., 2V).

At block 654, a respective programming voltage can be applied to access lines (e.g., word lines 422-1T, . . . , 422-NT, 522-1T, . . . , 522-XT illustrated in FIGS. 4-5) of the first erase block 405-1, 505-1, 505-2 sequentially from a first access line (e.g., word line 422-NT, 522-XT, or 522-YM illustrated in FIGS. 4-5) of the first erase block 405-1, 505-1, 505-2 to a second access line (e.g., word line 422-1T, 522-1T, or 522-1M illustrated in FIGS. 4-5) of the first erase block 405-1, 505-1 (and/or 505-2) to program memory cells of the first erase block 405-1, 505-1, 505-2 sequentially from a source side to a drain side. In this example, the first access line 422-NT, 522-XT (and/or 522-YM) is located adjacent to one or more dummy access lines (e.g., dummy word lines 431, 531 illustrated in FIGS. 4-5) separating the first erase block 405-1, 505-1, 505-2 from a second erase block (e.g., erase block 305-2, 405-2, 505-1, 505-2 illustrated in FIGS. 3-5) coupled to the first string. Further, the second access line 422-1T, 522-1T is located at the drain side of the first string. In some embodiments, to program the memory cells of the first erase block 405-1, 505-1, 505-2, a program pass voltage can be applied to unselected access lines of the first erase block 405-1, 505-1, 505-2 (e.g., subsequent to applying a seed pass voltage to those access lines coupled to the first string to pass the seed voltage applied through the sense line 220, 420, 520).

Alternatively, to program memory cells of the second erase block 405-2, 505-3 (and/or 505-2), a seed voltage can be applied through a source line (e.g., source line 229, 429, 529 illustrated in FIGS. 2, 4-5) coupled to the first string 225, 425, 525. Further, a seed pass voltage can be applied to those word lines 222, 422, 431, 522, 531 coupled to the first string 225, 425, 525 to pass the seed voltage through the word lines corresponding to the second erase block 405-2, 505-3 (and/or 505-2). In this example, a respective programming voltage can be applied to access lines (e.g., word lines 422-1B, . . . , 422-MB, 522-1B, . . . , 522-ZB and/or 522-1M, . . . , 522-YM illustrated in FIGS. 4-5) of the second erase block 405-2, 505-2, 505-3 sequentially from a third access line (e.g., word line 422-1B, 522-1M and/or 522-1B illustrated in FIGS. 4-5) of the second erase block 405-2, 505-2, 505-3 to a fourth access line (e.g., word line 422-MB, 522-YM and/or 522-ZB illustrated in FIGS. 4-5) of the second erase block 405-2, 505-2, 505-3 to program memory cells of the second erase block 405-2, 505-2, 505-3 sequentially from the drain side to the source side. In this example, the third access line 422-1B, 522-1M and/or 522-1B is located adjacent to the one or more dummy access lines 431, 531. Further, the fourth access line 422-MB, 522-ZB (and/or 522-YM) is located at the source side of the first string. In some embodiments, to program the memory cells of the second erase block 405-2, 505-2, 505-3, a program pass voltage can be applied to unselected access lines of the second erase block 405-2, 505-2, 505-3 (e.g., subsequent to applying a seed pass voltage to those access lines coupled to the first string to pass the seed voltage applied through the source line 229, 429, 529).

In some embodiments, program pass voltages having different voltage level can be applied respectively to multiple dummy access lines 431, 531 while programming the first erase block 405-1, 505-1, 505-2 or the second erase block 405-2, 505-2, 505-3. In some embodiments, a program verify operation performed on memory cells coupled to a respective access line of the first erase block 405-1, 505-1, 505-2, the second erase block 405-2, 505-2, 505-3, or both further involves ramping down (e.g., at the end of the program verify operation) a voltage level at which a respective select gate drain (SGD) line (e.g., SGD line 226, 426-1, 426-2, 526-1, 526-2 illustrated in FIGS. 2 and 4-5) or a respective select gate source (SGS) line (e.g., SGS line 227, 427-1, 427-2, 527-1, 527-2 illustrated in FIGS. 2 and 4-5) coupled to the first string 225, 425, 525 is biased while the memory cells coupled to the respective access line 222, 422, 522 are being program verified and subsequently ramping down a voltage level at which the respective access line 222, 422, 522 is biased during the program verify operation.

FIG. 7 illustrates an example computing system 701 having a memory system 790 for programming multiple erase blocks coupled to a same string in accordance with various embodiments of the present disclosure. As shown in FIG. 7, the memory system 790 includes a system controller 791 and a number of memory devices 700, which can be memory devices such as device 100 described in FIG. 1 (e.g., memory devices comprising memory arrays having multiple erase blocks coupled to common strings).

In some embodiments, the memory system 790 is a storage system. An example of a storage system is a solid-state drive (SSD). In some embodiments, the memory system 790 is a hybrid memory/storage sub-system. In general, the computing environment shown in FIG. 7 can include a host system 792 that uses the memory system 790. For example, the host system 792 can write data to the memory system 790 and read data from the memory system 790.

The memory system controller 791 (hereinafter referred to as “controller”) can communicate with the memory devices 700 to perform operations such as reading data, writing data, or erasing data at the memory devices 700 and other such operations. The controller 791 can include hardware such as one or more integrated circuits and/or discrete components, a buffer memory, or a combination thereof. The controller 791 can include a microcontroller, special purpose logic circuitry (e.g., a field programmable gate array (FPGA), an application specific integrated circuit (ASIC), etc.), or other suitable processing circuitry. The controller 700 can include a processing device (e.g., processor 794) configured to execute instructions stored in local memory (not shown).

In this example, the controller 791 includes a programming component 796 that can be responsible for facilitating performance of program and/or program verify operations in accordance with embodiments of the present disclosure. In some embodiments, the programming component 796 can include special purpose circuitry in the form of an ASIC, FPGA, state machine, and/or other logic circuitry that can allow the programming component 796 to orchestrate and/or perform operations described herein involving the memory device 700. The programming component 796 can further include storage locations (e.g., memory cells, latches, capacitors, etc.) that can be configured to store trim values (e.g., parameters) associated with those voltages (e.g., a voltage applied to a sense line, voltages applied to selected/unselected word lines, etc.) applied during performance of program and/or program verify operations.

In general, the controller 791 can receive commands or operations from the host system 792 and can convert the commands or operations into instructions or appropriate commands to achieve the desired access to the memory devices 700. The controller 791 can be responsible for other operations such as wear leveling operations, garbage collection operations, error detection and error-correcting code (ECC) operations, encryption operations, caching operations, and address translations between a logical block address and a physical block address that are associated with the memory devices 700.

The host system 792 can be a computing device such as a desktop computer, laptop computer, network server, mobile device, or other such computing device that includes a memory and a processing device. The host system 792 can include, or be coupled to, the memory system 790 so that the host system 792 can read data from or write data to the memory system 790. The host system 792 can be coupled to the memory system 790 via a physical host interface (not shown in FIG. 7). As used herein, “coupled to” generally refers to a connection between components, which can be an indirect communicative connection or direct communicative connection (e.g., without intervening components), whether wired or wireless, including connections such as electrical, optical, magnetic, etc. Examples of a physical host interface include, but are not limited to, a serial advanced technology attachment (SATA) interface, a peripheral component interconnect express (PCIe) interface, a universal flash storage (UFS) interface, a universal serial bus (USB) interface, Fibre Channel, Serial Attached SCSI (SAS), etc. The physical host interface can be used to transmit data between the host system 792 and the memory system 790. The host system 792 can further utilize an NVM Express (NVMe) interface to access the memory devices 700 when the memory system 790 is coupled with the host system 792 by the PCIe interface. The physical host interface can provide an interface for passing control, address, data, and other signals between the memory system 790 and the host system 792.

While the example memory system 790 in FIG. 7 has been illustrated as including the controller 791, in another embodiment of the present disclosure, a memory system 790 may not include a controller 791, and can instead rely upon external control (e.g., provided by a processor or controller separate from the memory system 790, such as by host 792 communicating directly with the memory devices 700).

Although the memory system 790 is shown as physically separate from the host 792, in a number of embodiments the memory system 790 can be embedded within the host 792. Alternatively, the memory system 790 can be removable from the host 792.

As used herein, an “apparatus” can refer to various structural components. For example, the computing system 701 shown in FIG. 7 can be considered an apparatus. Alternatively, the host 792, the controller 704, and the memory device 700 might each separately be considered an apparatus.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, which can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

The figures herein follow a numbering convention in which the first digit or digits correspond to the drawing figure number and the remaining digits identify an element or component in the drawing. Similar elements or components between different figures may be identified by the use of similar digits. For example, 102 may reference element “02” in FIG. 1, and a similar element may be referenced as 202 in FIG. 2. As will be appreciated, elements shown in the various embodiments herein can be added, exchanged, and/or eliminated so as to provide a number of additional embodiments of the present disclosure.

For the purposes of the present disclosure, the phrase “A and/or B” means (A), (B), (A) or (B), or (A and B). For the purposes of the present disclosure, the phrase “A, B, and/or C” means (A), (B), (C), (A and B), (A and C), (B and C), or (A, B and C). Additionally, the phrase “at least one of A and B” means one or more of (A) or one or more of (B), or one or more of (A) and one or more of (B) such that both one or more of (A) and one or more of (B) is not required.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
applying, to program memory cells of a first erase block coupled to a first string of a memory array, a seed voltage through a sense line coupled to the first string; and
applying, to program memory cells of the first erase block sequentially from a source side to a drain side, a respective programming voltage to access lines of the first erase block sequentially from a first access line of the first erase block to a second access line of the first erase block, wherein:
the first access line is located adjacent to one or more dummy access lines separating the first erase block from a second erase block coupled to the first string; and
the second access line is located at the drain side of the first string.

2. The method of claim 1, further comprising:
applying, to program memory cells of the second erase block, a seed voltage through a source line coupled to the first string;
applying a seed pass voltage having a voltage level lower than that of the seed voltage to one or more access lines coupled to the first string; and
applying, to program memory cells of the second erase block sequentially from the drain side to the source side, a respective programming voltage to access lines of the second erase block sequentially from a third access line of the second erase block to a fourth access line of the second erase block, wherein:
the third access line is located adjacent to the one or more dummy access lines; and
the fourth access line is located at the source side of the first string.

3. The method of claim 1, wherein:
programming the memory cells of the first erase block further comprises:
applying a seed pass voltage to access lines coupled to the first string to pass the seed voltage applied through the sense line; and
applying, subsequent to applying the seed pass voltage to the access lines coupled to the first string, a program pass voltage to unselected access lines of at least the first and second erase blocks; and
programming the memory cells of the second erase block further comprises:
applying a seed pass voltage to access lines coupled to the first string to pass the seed voltage applied through the sense line; and
applying, subsequent to applying the seed pass voltage to the access lines coupled to the first string, a program pass voltage to unselected access lines of at least the first and second erase blocks.

4. The method of claim 1, wherein programming the memory cells of the first erase block or the second erase block further comprises applying program pass voltages having different voltage level respectively to multiple dummy access lines.

5. The method of claim 1, further comprising performing a program verify operation on memory cells coupled to a respective access line of the first erase block, the second erase block, or both further comprises:
at the end of the program verify operation, ramping down a voltage level at which a respective select gate drain (SGD) line and/or a respective select gate source (SGS) line coupled to the first string is biased during the program verify operation; and
subsequently ramping down a voltage level at which the respective access lines are biased during the program verify operation.

6. An apparatus, comprising:
a memory array comprising a first string of memory cells, wherein the first string comprises:
memory cells coupled to a first group of access lines and corresponding to a first erase block, the first erase block further comprising:
a first access line located adjacent to one or more third access lines; and
a second access line located at a drain side of the first string; and
memory cells coupled to a second group of access lines and corresponding to a second erase block, the second erase block further comprising:
a first access line of the second erase block located adjacent to the one or more third access lines; and
a second access line of the second erase block located at a source side of the first string; and
a controller coupled to the memory array and configured to:
program memory cells of the first erase block sequentially from a group of memory cells coupled to the first access line of the first erase block to a group of memory cells coupled to the second access line of the first erase block; and
program memory cells of the second erase block sequentially from a group of memory cells coupled to the first access line of the second erase block to a group of memory cells coupled to the second access line of the second erase block.

7. The apparatus of claim 6, wherein the drain side of the first string is coupled to a sense line of the memory array and the source side of the first string is coupled to a source line of the memory array.

8. The apparatus of claim 6, wherein the first string further comprises memory cells coupled to a fourth group of access lines and corresponding to a third erase block, the third erase block located between the first erase block and the second erase block, wherein a first portion of the one or more third access lines is located between the second and third erase blocks, while a second portion of the one or more third access lines are located between the first and the third erase blocks.

9. The apparatus of claim 8, wherein the controller is configured to program the memory cells of the third erase block sequentially from a group of memory cells coupled to a first access line of the third erase block to a group of memory cells coupled to a second access line of the third erase block, wherein:
the first access line of the third erase block is located adjacent to the first portion of the one or more third access lines; and
the second access line of the third erase block is located adjacent to the second portion of the one or more third access lines.

10. The apparatus of claim 9, wherein the controller is configured to program the memory cells of the third erase block prior to the first erase block being programmed.

11. The apparatus of claim 9, wherein the controller is further configured to, in order to program the memory cells of the third erase block:
apply a seed voltage through a sense line coupled to the first string;
apply a seed pass voltage to one or more word lines coupled to the first string to pass the seed voltage applied through the sense line;
apply a programming voltage to a selected access line of the third erase block; and
apply, subsequent to applying the seed pass voltage to the access lines coupled to the first string, a program pass voltage to unselected access lines of at least the first, second, and third erase blocks and to the one or more third access lines.

12. The apparatus of claim 8, wherein the controller is configured to program the memory cells of the third erase block sequentially from a group of memory cells coupled to a first access line of the third erase block to a group of memory cells coupled to a second access line of the third erase block, wherein:
the first access line of the third erase block is located adjacent to the second portion of the one or more third access lines; and
the second access line of the third erase block is located adjacent to the first portion of the one or more third access lines.

13. The apparatus of claim 12, wherein the controller is configured to program the memory cells of the third erase block prior to the memory cells of the second erase block being programmed.

14. The apparatus of claim 13, wherein the controller is further configured to, in order to program the memory cells of the third erase block:
apply a seed voltage through a source line coupled to the first string;
apply a seed pass voltage to one or more word lines coupled to the first string to pass the seed voltage applied through the source line;
apply a programming voltage to a selected access line of the third erase block; and
apply, subsequent to applying the seed pass voltage to the access lines coupled to the first string, a program pass voltage to unselected access lines of the first, second, and third erase blocks and to the one or more third access lines.

15. An apparatus, comprising:
a memory array comprising a first string of memory cells, the first string comprising:
a first group of memory cells coupled to a first group of access lines and corresponding to a first erase block, the first group of access lines further comprising:
a first access line of the first group of access lines is located adjacent to one or more third access lines; and
a second access line of the first group of access lines is located at a drain side of the first string; and
a second group of memory cells coupled to a second group of access lines and corresponding to a second erase block, the second group of access lines further comprising:
a first access line of the second group of access lines is located adjacent to the one or more third access lines that are located between the first and second erase blocks; and
a second access line of the second group of access lines is located at a source side of the first string; and
a controller coupled to the memory array and configured to:
program memory cells of the first erase block sequentially from memory cells coupled to the first access line of the first erase block to memory cells coupled to the second access line of the first erase block and using a seed voltage applied through a sense line coupled to the first string; and
program memory cells of the second erase block sequentially from memory cells coupled to the first access line of the second erase block to memory cells coupled to the second access line of the second erase block and using a seed voltage applied through a source line coupled to the first string.

16. The apparatus of claim 15, wherein the controller is further configured to, in order to program the memory cells of the first erase block:
apply the seed voltage through the sense line coupled to the first string;
apply a seed pass voltage to one or more word lines coupled to the first string to pass the seed voltage applied through the source line;
apply a programming voltage to a selected access line of the first erase block; and
apply, subsequent to applying the seed pass voltage to the access lines coupled to the first string, a first program pass voltage to unselected access lines of the first and second erase blocks and to the one or more third access lines.

17. The apparatus of claim 16, wherein the controller is further configured to, in order to program the memory cells of the first erase block:
apply a second program pass voltage to access lines of the second erase block, while the first erase block is being programmed, wherein the second program pass voltage has a voltage level lower than the first program pass voltage.

18. The apparatus of claim 16, wherein the one or more third access lines correspond to a plurality of dummy access lines coupled to dummy memory cells, and wherein the controller is further configured to, in order to program the memory cells of the first erase block:
apply, respectively to the plurality of dummy access lines, program pass voltages having different voltage levels.

19. The apparatus of claim 15, wherein the controller is configured to, at the end of a program verify operation performed on memory cells coupled to a respective access line of the second erase block:
ramp down a voltage level at which a respective select gate drain (SGD) line and/or a respective select gate source (SGS) line coupled to the first string is biased during the program verify operation; and
subsequently ramp down a voltage level at which the respective access lines are biased during the program verify operation.

20. The apparatus of claim 15, wherein:
memory cells coupled to the one or more third access lines correspond to dummy memory cells; and
the controller is configured to program the dummy memory cells to a higher threshold voltage than a threshold voltage corresponding to an erased state of memory cells.
